(19) United States
(12) Patent Application Publication
(10) Pub. No.: US 2026/0096047 A1
(43) Pub. Date: Apr. 2, 2026

(54) PATCH PANEL SUPPORT AND METHOD OF ASSEMBLING EQUIPMENT RACKS FOR A DATA CENTER

(71) Applicant: MODULARMC, LLC, Tysons, VA (US)

(72) Inventors: Charles Cameron LEWIS, Mechanicsville, VA (US); Mark Edward BOWMAN, Midlothian, VA (US); Andrea Marie SHERLOCK, Fredericksburg, VA (US); Scotty Daryl LAWSON, JR., Richmond, VA (US)

(73) Assignee: MODULARMC, LLC, Tysons, VA (US)

(21) Appl. No.: 19/345,900

(22) Filed: Sep. 30, 2025

Related U.S. Application Data
(60) Provisional application No. 63/701,361, filed on Sep. 30, 2024.

(51) Int. Cl. H05K 7/14

(52) U.S. Cl. CPC H05K 7/1491; H05K 7/1489

(57) ABSTRACT

A patch panel support (PPS) and method of assembly of data center electronic equipment racks is provided that allows the patch panels that are normally mounted in the lower frame of the equipment rack—where the electronic equipment is housed—to be mounted in the upper frame by means of a frame plate connectable to cable trays installed in the upper frame. The PPS further includes a mounting mechanism for mounting one patch panel to the frame plate over each of the one or more cable trays. The resulting reconfiguration of the equipment rack allows the components in the upper frame of the equipment rack to be pre-assembled off-site without the constraints imposed by on-site construction. Additionally, the PPS frees up space in the lower frame of the rack for additional electronic equipment by relocating the patch panels to the upper frame.

### CROSS-REFERENCE TO RELATED APPLICATIONS

This application claims benefit of priority to U.S. Provisional Application No. 63/701,361 filed Sep. 30, 2024, the entire contents of which are incorporated herein by reference.

### FIELD OF THE INVENTION

This invention relates to electronic equipment racks used in data centers and is specifically concerned with a multi-tiered patch panel support that allows the patch panels that are normally mounted in a lower frame of such equipment racks to be mounted to cable trays disposed in the upper frame of the racks.

### BACKGROUND

In the new era of AI and cloud computing, the increased demand for speed and bandwidth have resulted in a demand for data centers having more rows of equipment racks for supporting the servers, switches, and other electronic equipment. The increased demand for speed and bandwidth has also resulted in a demand for racks that can house a denser array of electronic equipment, as well as a demand for more compact, multi-tiered arrays of optical cables that can interconnect the rows of electronic equipment housed by the racks. However, such additional rows of racks and multi-tiered arrays of optical cables increase the construction time required for pathway, rack, and cabling installation in the data center.

In conventional data center construction, rows of equipment racks are installed on-site on the floor of the data center. Each equipment rack comprises both a lower section and an upper section of a frame that forms part of the cooling system of the data center known as a hot aisle containment (HAC) frame. The lower HAC frame contains either an open rack or a cabinet that contains servers, switches, and other electronic equipment. The upper HAC frame supports cable trays above the open racks or cabinets. These cable trays extend between equipment racks arranged in the same row, and the upper frame section may support as many as four vertically-space tiers of trays. Each tray supports a bundle of optical fiber cables that extends between the equipment racks and optically interconnects the electronic equipment housed within the row of equipment racks.

Patch panels are mounted in the open rack or cabinet in the lower HAC frame. These panels are used to optically connect the cables in the trays mounted in the upper HAC frame to the electronic equipment housed in the open rack or cabinet in the lower HAC frame. One patch panel is required for each cable tray. Each patch panel has an inlet that receives a bulk fiber optic cable connected to all the optical cables in a particular tray that feeds the equipment in the open rack or cabinet below, and a plurality of optical outlets. The patch panel routes specific fibers of the bulk cable to a particular one of its optical outlet connectors, each of which is to be connected to a particular piece of electronic equipment. Patching cables complete the optical coupling between the outlet connectors of the patch panels and the electronic equipment. In conventional data center construction, the patch panels.

In a conventional data center construction sequence, the patch panels are first mounted in the open rack or cabinet in the lower HAC frame. Cable trays are then installed in the upper HAC frames over the rows of racks containing the patch panels. The optical cables are then pulled through the cable trays. The bulk fiber optic cable associated with each of the trays of optical cable is then connected to the inlet of one of the patch panels. This onsite step requires the workers to stand on a ladder or scaffold to access the optical cables in the trays above the racks. Finally, the integrity of the optical cables is then tested to make sure all fibers and connections are operational.

### SUMMARY OF THE INVENTION

The applicant has observed that the onsite construction steps of patch panel installation, cable pull-through, cable connection to the patch panels, and cable testing substantially extends the time by which the data center can become operational. The recent increase in the amount and density of equipment being installed in data centers is making the completion of these onsite steps even longer.

To shorten and simplify these construction steps, the invention comprises a multi-tier patch panel support (hereinafter abbreviated to PPS) which mounts the patch panels to the cable trays disposed within the upper HAC frame. To this end, the PPS comprises a frame plate attachable to the one or more cable trays, and a mounting mechanism for mounting one patch panel to the frame plate over each of the one or more cable trays. The frame plate includes a plurality of U-shaped attachment members that attach to the one or more cable trays by capturing an edge of the cable trays such that the frame plate is suspended therefrom. The mounting mechanism includes a column of screw holes on opposite sides of the frame plate that are registrable with screw holes on opposite sides of each of the patch panels such that each patch panel may be screw mounted to the frame plate in a position overhanging one of the cable trays. A pair of side plates are connected to opposite sides of the frame plate which not only provide rigidity and support, but also include one or more vertical cable managers for managing patch cables connected to the patch panels.

In the method of the invention, the upper HAC is preassembled offsite in the following manner. First, the cable trays are mounted in the upper HAC frame. Cable bundles are then pulled through the cable trays. The frame plate of the PPS is then mounted onto the cable trays by capturing side edges of the trays in the U-shaped attachment members on the frame plate. Horizontal cable managers are next mounted onto the frame plate via the same mounting mechanism for the patch panels (i.e. the vertically oriented rows of tapped screw mounting holes on either side of the plate). The patch panels are then mounted to the frame plate via the screw holes of the mounting mechanism in positions overlying the cable bundle in each of the one or more cable trays. The patch panels are then optically connected to the bulk fiber optic cable connected to the particular cables that will ultimately connect to the equipment in the lower HAC frame. Individual cables of patch cable bundles are next connected to the back of the patch panels. The optical cables are then labeled and tested. Finally, the patch cable bundles are mounted to the vertical cable managers in the side panels of the PPS.

The inventive PPS allows all of the aforementioned method the steps to be performed offsite in the upper HAC frame before it is lifted and connected to the lower HAC frame. This obviates the need for the assembly workers to stand on a ladder when connecting the optical cables to the electronic equipment in the lower HAC frame of the rack. The PPS also allows the bulk fiber optic cable to be connected to the patching panels via the HAC pathway space in the data center rather than through the much more limited space within the equipment rack.

In one preferred method of the invention, the lower HAC frames of the racks are populated with electronic equipment and shipped to the data center, where they are positioned and secured to the floor. The upper, pre-assembled HAC frames are then shipped to the data center, and lifted and mounted onto their respective lower HAC frames. The patch cable bundles are then connected to their respective pieces of the electronic equipment housed in the lower HAC frame. In another preferred method of the invention, both the upper and lower HAC frames are pre-assembled and the entire structure is shipped to the site and installed, where patch cables are connected between the PPS mounted patch panels and the equipment in the open racks or cabinets below, minimizing the onsite time required for the cabling step. The PPS, in allowing most construction steps to be conducted offsite under well-lighted and easy access conditions, substantially shortens the time necessary for the final onsite assembly of the rows of equipment racks in the data center. This in turn results in a building that is operational much sooner—perhaps by as much as three or more months—than current practices allow.

In addition to making installations faster and more efficient, relocating the patch panels out of the racks or cabinets in the lower HAC frame to the PPS in the upper HAC frame creates more space within the racks or cabinets for additional equipment and the tens of thousands of optical strands that interconnect in the racks.

### DESCRIPTION OF THE SEVERAL FIGURES

FIG. 1A is a perspective view of an equipment rack with the PPS installed in a much smaller HAC configuration than typical construction;

FIG. 1B is a front view of the equipment rack of FIG. 1A;

FIG. 1C is a side view of the equipment rack of FIG. 1A;

FIG. 2 a top view of the equipment rack of FIG. 1A;

FIG. 3A is a back perspective view of the PPS;

FIGS. 3B and 3C are front and back views of the frame plate of the PPS.

FIGS. 4A-4C are assembly drawings, wherein

FIG. 4A is a front, perspective view of an upper HAC frame with both cable trays and the PPS installed;

FIG. 4B is a front, perspective view of the upper HAC frame of FIG. 4A with patch panels and patch cables mounted on the PPS and further showing optical cables disposed in the cable trays and, and

FIG. 4C is a front, perspective view of the upper HAC frame assembled to the lower HAC frame containing an equipment rack with the patch cables draped in the area where the electronic equipment is to be installed.

### DETAILED DESCRIPTION OF A PREFERRED EMBODIMENT:

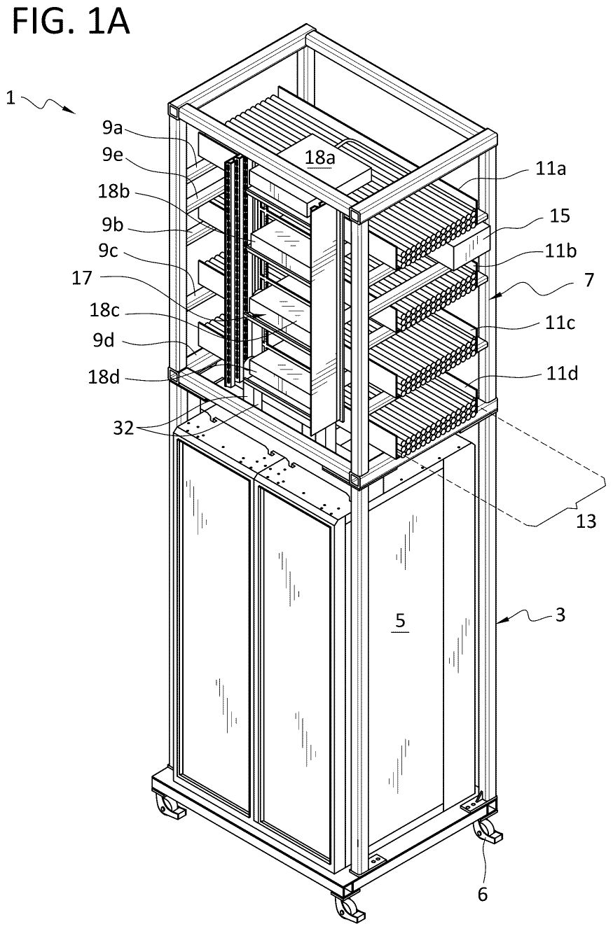

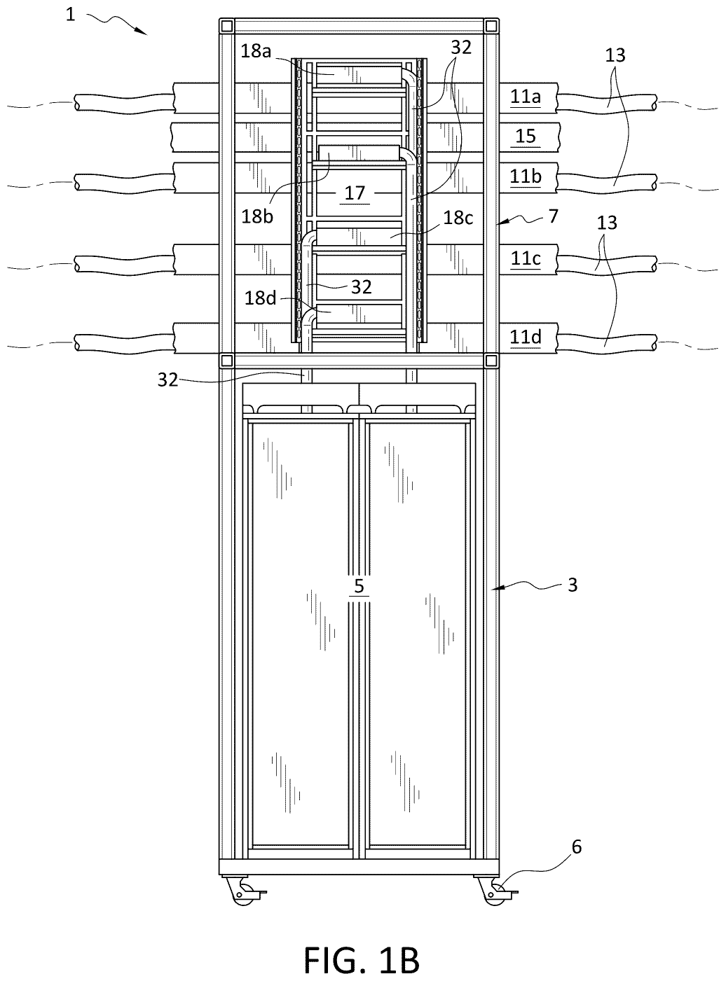

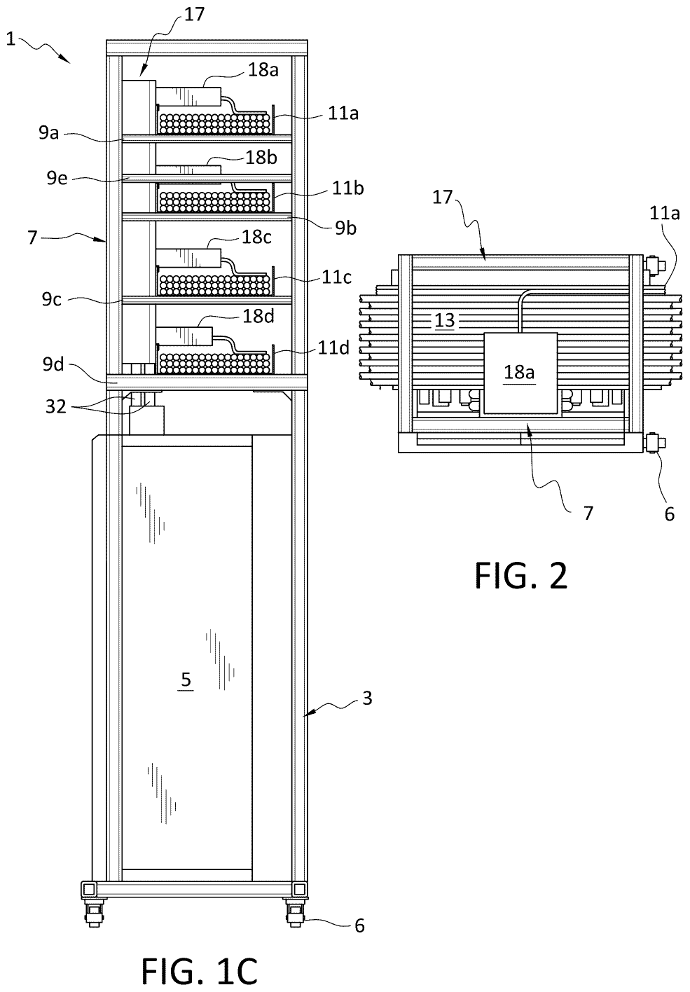

FIGS. 1A-1C and FIG. 2 Illustrate a rack 1 with the patch panel support (PPS) 17 installed.

The rack 1 includes a lower hot aisle containment (HAC) frame 3 containing a rack 5 for housing electronic equipment such as servers, switches, and the like. While the rack 5 takes the form of cabinets in this example, such racks may also be open-framed. The term “rack” in this application encompasses cabinets, open frames, and all other structures capable of supporting an arrangement of electronic equipment. While the lower HAC frame 3 includes casters 6 in this embodiment for facilitating movement of the rack 1, these frames 3 are normally bolted onto a skid (not shown).

The rack 1 further includes an upper HAC frame 7 that is bolted onto the top end of the lower HAC frame 3 in the position shown in FIG. 1A. In this example, the upper HAC frame 7 includes horizontally disposed tray support members 9a-d on either side for supporting tiered cable trays 11a-d, respectively. Each cable tray 11a-d in turn supports a bundle of cables 13 that interconnects electronic equipment housed in the rack 5 to the electronic equipment housed in other racks 1. These cables 13 are typically optical cables but may also include electrically-conductive cables for carrying electrical power or signals. Finally, in this example, rack 1 includes a switching bus bar 15 supported on horizontally disposed support member 9e. While the cable trays 11a-d and cables 13 are illustrated as being cut-off at the sides of the upper HAC frame in FIG. 1A, they in fact extend well beyond the frame 7 as shown in FIG. 1B into flanking racks 1 that are not shown.

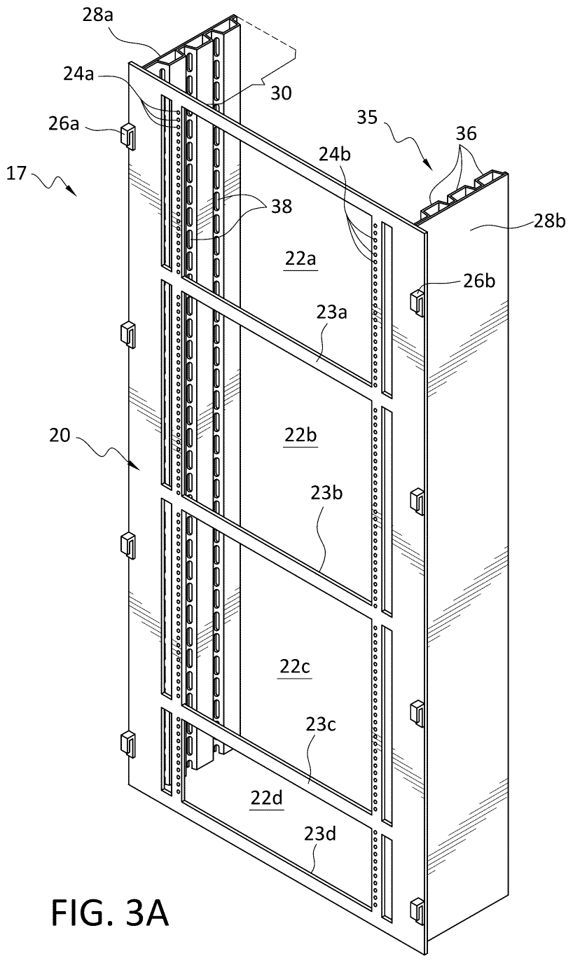

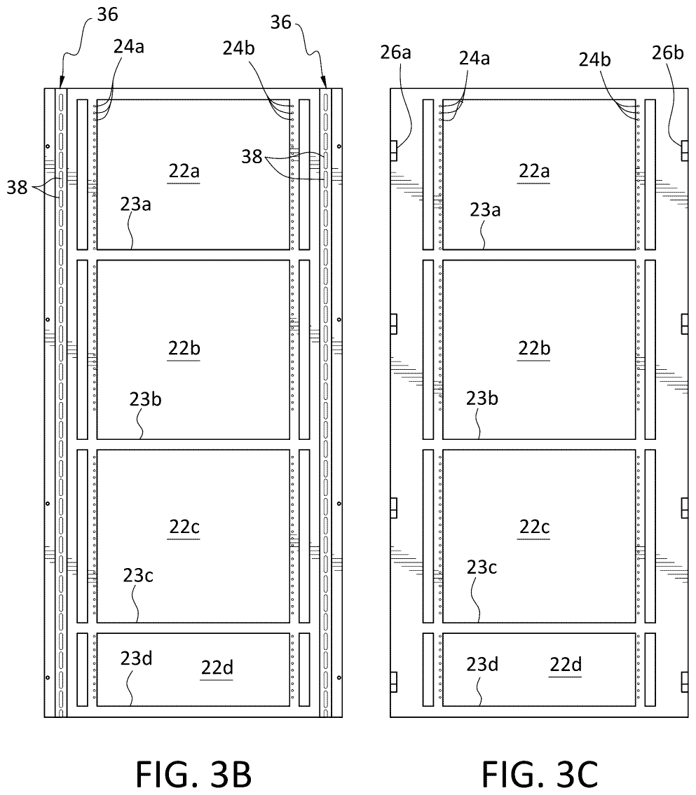

The patch panel support (PPS) 17 is mounted within the upper HAC frame 7. Since the number of patch panels will correspond to the number of cable trays supported by the upper HAC frame 7, the four cable trays 11a-d necessitate the support of four patch panels 18a-d by the PPS 17. As is best seen in FIGS. 3A-3C, the PPS 17 includes a frame plate 20 having rectangular apertures 22a-d defined by cross members 23a-d for receiving the patch panels 18a-d. On either side of the apertures 22a-d is a mounting mechanism for the patch panels 18a-d including vertically oriented rows 24a, b of tapped screw mounting holes for receiving screws (not shown) that secure the front ends of the patch panels 18a-d to the frame plate 20. While not specifically shown in the figures, the front of each of the patch panels 18a-d includes a pair of opposing mounting ears on either side which include holes for receiving the mounting screws. The provision of such rows 24a, b of uniformly spaced screw holes allows the vertical position of the patch panels to be adjusted so that each one is in a proper vertical position relative to its respective cable tray 11a-d. Each of the patch panels 18a-d also includes an inlet for receiving a bulk fiber optic cable connected to all the optical fibers in a particular tray 11a-d that feeds the equipment in the rack 5 below, as well as a plurality of optical outlets connectable to specific cables in a patch cable bundle, even though these particular structures are not illustrated. As is shown in FIGS. 3A and 3C, two vertical rows of U-shaped attachment members in the form of hooks 26a, b are provided on either side of the front face of frame plate 20. The hooks in these rows 26a, b are spaced to align with a side edge of one of the cable trays 11a-d. The frame plate 20 of the PPS 17 is installed by inserting it onto the upper HAC frame 7 and capturing the side edges of the cable trays 11a-d with the hooks 26a, b. While the U-shaped attachment members in this example of the invention take the form of hooks 26a, b, they may also take the form of U-shaped clamps or brackets that are further secured on the side edges of the cable trays via screws or bolts.

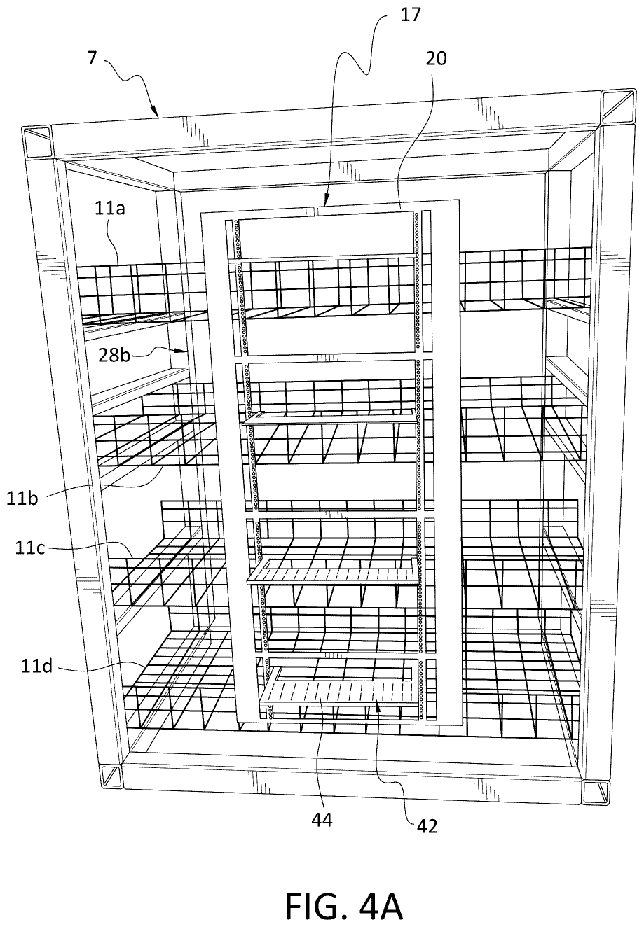

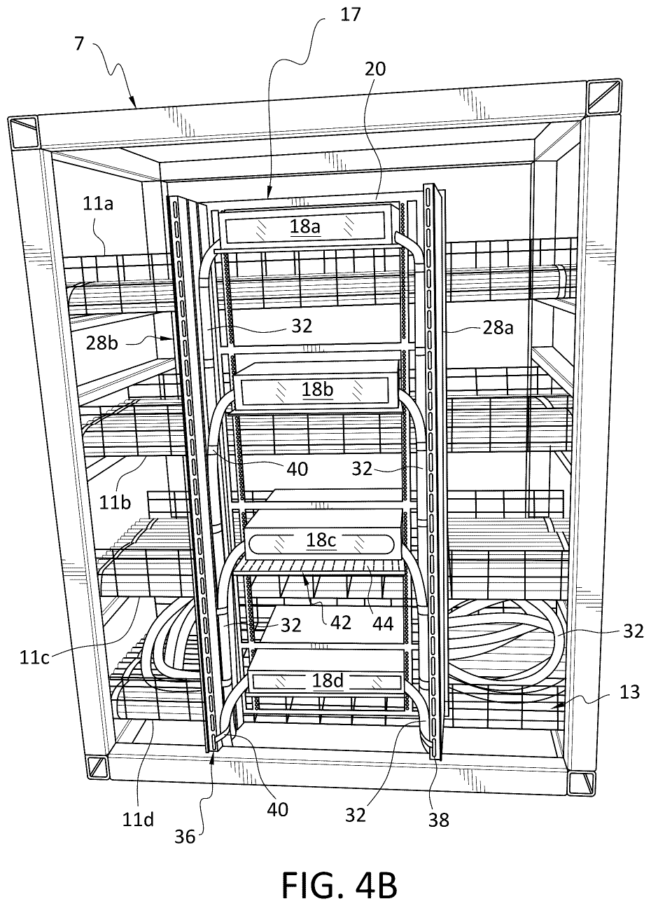

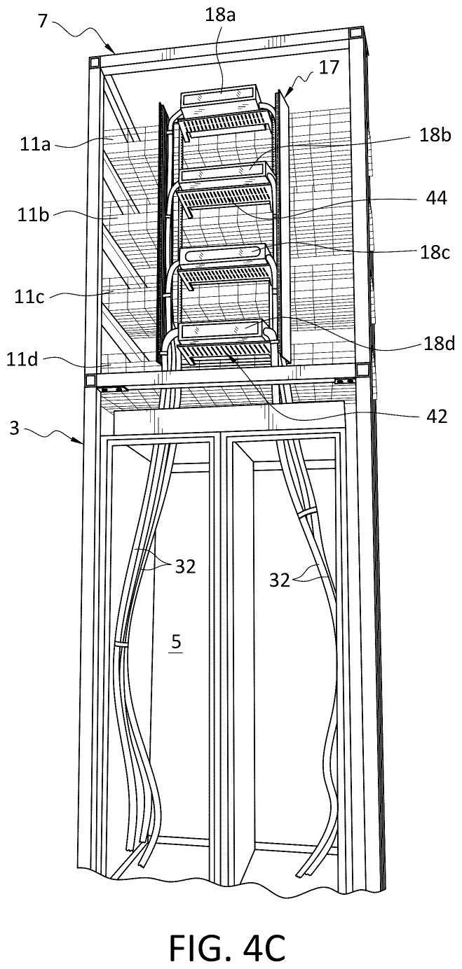

With reference to FIG. 3A, the PPS 17 further includes a pair of side plates 28a, b. These side plates 28a, b are bolted onto the sides of the frame plate 20 in a conventional manner. These side plates 28a, b not only serve to rigidify the PPS, but further include vertical cable managers 30 for patch cable bundles 32 (shown in FIG. 4B) that optically connect the patch panels 18a-d to electronic equipment contained within the cabinet 5 or rack in the lower frame 3. These vertical cable managers 30 are comprised of spline walls 35 formed from three raised cable supports 36. Each of the raised cable supports includes opposing rows of slots 38 for receiving adhesive, hook-and-eye strips 40 (shown in FIG. 4B) such as Velcro®. In use, the strips 40 are threaded through the slots 38 to grasp and support the patch cable bundles 32 as best seen in FIG. 4B. The PPS 17 is used in conjunction with horizontal cable managers 42 that include support plates 44. The support plates 44 are screwed onto the frame plate 20 via the same vertically oriented rows 24a, b of tapped screw mounting holes used to mount the patch panels 18a-d. These horizontal cable managers 42 support the patch cable bundles 32 in positions along the sides of the patch panels. The support plates 44 further help to position and support the patch panels 18a-d during their installation in the PPS 17.

There are two preferred assembly methods of the invention. Each such method includes the following fourteen steps, of which the use of the PPS 17 advantageously allows at least the first ten steps to be performed at location offsite from the building where the equipment racks 1 are ultimately installed:
1. Installing cable trays 11a-d in the upper HAC frame 7.
2. Mounting the frame plate 20 of the PPS 17 to side edges of the cable trays 11a-d via the two vertical rows of hooks 26a, b or other U-shaped attachment members.
3. Installing the horizontal cable managers 42 onto the frame plate 20 via the vertically oriented rows 24a, b of tapped screw mounting holes on either side of the plate 20.

FIG. 4A illustrates what the upper HAC frame 7 and assembled parts should look like when these steps are completed.
4. Pulling the fiberoptic cable bundle 13 through the cable trays 11a-d.
5. Installing the patch panels 18a-d on the PPS via the rows 24a, b of tapped screw mounting holes on either side of the plate 20.
6. Bolting the side panels 28a, 28b to the frame plate 20
7. Connecting the patch panels 18a-d to the bulk fiber optic cable connected to the particular cables 13 that will ultimately connect to the equipment in the rack 5.
8. Connecting individual cables of the patch cable bundles 32 into the back of the patch panels 18a-d.
9. Labeling and testing cables.
10. Installing vertical cable managers 30 by mounting the patch cable bundles 32 to the raised cable supports 36 of the PPS with the hook-and-eye strips 40.

FIG. 4B illustrates what the upper HAC frame 7 and assembled parts should look like when these steps are completed.
11. Lift and bolt the upper HAC frame 7 and parts assembled thereto onto the lower HAC frame 3.

FIG. 4C illustrates what the rack 1 should look like when this step is completed.
12. Roll prepopulated racks 5 into the lower HAC frame 3.
13. Install individual cables from the patch cord bundle 32 from the front of the patch panels 18a-d in the PPS to the electronic equipment located in the lower HAC frame 3.
14. Manage and dress cables from the patch cord bundle 32 to the vertical cable management raised cable supports 36.

The first preferred method includes the following additional steps:
Assemble populated racks 5 offsite and deliver to site.
Concurrently manufacture, assemble, and test upper HAC frame 7 and installed parts offsite.
Ship upper HAC frame 7 and installed parts to site and install on top of previously installed lower HAC frame 3 with its populated rack 5.
Connect cables of patch cable bundle 32 from PPS 17 above to the equipment in the racks 5.

The second preferred method includes the following additional steps:
Assemble lower HAC frame structure 3 offsite.
Concurrently manufacture, assemble, and test upper HAC frame 3 and assembled components offsite.
Install assembled upper HAC frame 7 on top of the lower HAC frame structure 3 offsite.
Install racks 5 and equipment in the lower HAC frame 3.
Connect individual cables of the patch cable bundles 32 into the back of the patch panels 18a-d.
Ship one or more rows of the fully assembled racks 1 to site and install in the building.

Because the use of the PPS allows at least ten of the fourteen rack assembly steps to be completed offsite under well-lighted and access-friendly conditions, the construction and installation of the racks 1 is greatly expedited, resulting in an operational data center three or more months sooner. Moreover, the positioning of the patch panels 18a-d into the upper HAC frame 7 and out of the racks 5 in the lower HAC frame 3 frees up space in the racks 1 for additional electronic equipment.

Although the invention has been described in detail with particular reference to a preferred embodiment, it will be understood that variations and modifications can be affected within the spirit and scope of the invention. All such variations and modifications are within the scope of this invention, which is limited only by the terms of the appended claims and their equivalents.

1. A patch panel support (PPS) for an electronic equipment rack, wherein the rack includes an upper frame that supports one or more cable trays, and a lower frame that supports electronic equipment, comprising:
a frame plate attachable to the one or more cable trays, and
a mounting mechanism for mounting one patch panel to the frame plate over each of the one or more cable trays.

2. The PPS defined in claim 1, wherein the frame plate includes a plurality of U-shaped attachment members that attach to the one or more cable trays by capturing an edge of the cable trays such that the frame plate is suspended therefrom.

3. The PPS defined in claim 1, further comprising a pair of side plates connected to opposite sides of the frame plate to provide rigidity and support therefor.

4. The PPS defined in claim 1, wherein the mounting mechanism includes a column of screw holes on opposite sides of the frame plate that are registrable with screw holes on opposite sides of each of the patch panels such that each patch panel may be screw mounted to the frame plate in a position overhanging one of the cable trays.

5. The PPS defined in claim 3, wherein each of the side plates includes one or more cable managers for managing patch cables connected to the patch panel.

6. The PPS defined in claim 4, wherein each cable manager includes a spline wall formed from one or more raised cable supports, and each spline wall includes slots for threading strips of self-adhesive material that grasp and support the patch cables.

7. The PPS defined in claim 1, wherein the upper and lower frames are hot aisle containment (HAC) frames.

8. A patch panel support (PPS) for an electronic equipment rack disposed in a data center, the rack having an upper frame that supports one or more cable trays, and a lower frame that supports electronic equipment, comprising:
a frame plate attachable to the one or more cable trays and having apertures for receiving one or more patch panels,
a mounting mechanism for mounting one patch panel to the frame plate over each of the one or more cable trays,
wherein the frame plate includes a plurality of U-shaped attachment members that attach to the one or more cable trays by capturing an edge of the cable trays such that the frame plate is suspended therefrom.

9. The PPS defined in claim 8, wherein the mounting mechanism includes a column of screw holes on opposite sides of the frame plate that are registrable with screw holes on opposite sides of each of the patch panels such that each patch panel may be screw mounted to the frame plate in a position overhanging one of the cable trays.

10. The PPS defined in claim 8, further comprising a pair of side plates connected to opposite sides of the frame plate to provide rigidity and support therefor, wherein the side plates include cable managers for managing patch cables connected to the patch panel.

11. A method for assembling an electronic equipment rack for installation within a building, wherein the rack includes a lower frame for housing electronic equipment, an upper frame for supporting one or more cable trays, comprising the following steps performed offsite from the building:
mounting the one or more cable trays in the upper frame;
attaching a patch panel support (PPS) to the one or more cable trays in the upper frame,
pulling a cable bundle through the one or more cable trays, and
mounting one patch panel to the patch panel support in a position overlying the cable bundle for each of the one or more cable trays.

12. The assembly method defined in claim 11, wherein the PPS includes a frame plate that is mounted onto the one or more cable trays.

13. The assembly method defined in claim 12, wherein the frame plate is installed onto the one or more cable trays by U-shaped members that capture an edge of the one or more cable trays such that the frame plate is suspended therefrom.

14. The assembly method defined in claim 11, further comprising the following further offsite steps:
connecting the patch panel to a bulk fiber optic cable that in turn is connected to selected fiber optic cables in the tray that are to be connected to electronic equipment housed within the rack:
connecting patch cables to connectors of the patch panel, and
labeling and testing the patch cables.

15. The assembly method defined in claim 14, further comprising the following further offsite steps:
providing the PPS with vertical cable managers, and
installing the patch cables into the vertical cable managers.

16. The assembly method defined in claim 14, further comprising the following further steps:
installing equipment racks in the lower frame that have been populated with electronic equipment,
lifting and connecting the upper frame to the lower frame, and
connecting the patch cables to the electric equipment housed within the rack.

17. The assembly method defined in claim 16, wherein the lower frame, after the populated equipment racks have been installed therein at an offsite location, is delivered and positioned in the building before the upper frame is delivered to the building.

18. The assembly method defined in claim 16, wherein the steps of installing equipment racks in the lower frame that have been populated with electronic equipment, lifting and connecting the upper frame to the lower frame, and connecting the patch cables to the electric equipment housed within the rack are all conducted at an offsite location, and the resulting assembled electronic equipment rack is delivered to the building.
